(19) United States
(12) Patent Application Publication
(10) Pub. No.: US 2011/0139615 A1
(43) Pub. Date: Jun. 16, 2011

(54) SPUTTERING TARGET MATERIAL

(75) Inventors: Noriyuki TATSUMI, Kasumigaura (JP); Kouichi Isaka, Ishioka (JP); Katsutoshi Honya, Tsuchiura (JP); Masami Odakura, Tsukuba (JP); Tatsuya Tonogi, Tsuchiura (JP)

(73) Assignee: HITACHI CABLE, LTD.

(21) Appl. No.: 12/899,038

(22) Filed: Oct. 6, 2010

(30) Foreign Application Priority Data
Dec. 16, 2009 (JP) 2009-284945

(51) Int. Cl. C23C 14/34; C23C 14/14

(52) U.S. Cl. 204/298.13

(57) ABSTRACT

A sputtering target material includes a copper alloy made of an oxygen free copper with a purity of 99.99% or more doped with Ag of 200 to 2000 ppm. The sputtering target material is formed by casting and rolling. An average grain size of crystal is 30 to 100 μm. A ratio (220)/(111) which is a ratio of an orientation ratio of (220) plane to an orientation ratio of (111) plane calculated based on a peak intensity measurement of an X-ray diffraction at a sputtering surface is 6 or less and a standard deviation indicating a dispersion in the ratio (220)/(111) is 10 or less.

The present application is based on Japanese Patent Application No. 2009-284945 filed on Dec. 16, 2009, the entire contents of which are incorporated herein by reference.

### BACKGROUND OF THE INVENTION

1. Field of the Invention

The present invention relates to a sputtering target material to be used for sputtering for forming e.g. a thin film on substrate.

2. Description of the Related Art

In late years, miniaturization of TFT (thin film transistor) array wiring has been demanded for higher definition of a large-sized display panel. As a wiring material, application of copper (Cu) has started since Cu has electric resistivity lower than that of aluminum (Al). It is expected that changes of the wiring material from Al, which has been used as the mainstream of the wiring material, to Cu will advance. It is because that reduction in the resistivity of the wiring material will be further required in order to respond to further higher definition 4K×2K (4000×2000 pixels grade) and higher speed operation such as operating frequency of 120 Hz and 240 Hz.

In the sputtering process carried out by means of a target material when minute Cu wiring pattern is formed on a substrate, a surface of the target material is eroded by sputtering for a long time. If a degree of convexo-concave (surface irregularity) of an eroded part (erosion part) is increased, abnormal electrical discharge will occur at the erosion part. There is a disadvantage in that manufacturing yield of the Cu wiring falls, since the target material is melt at a high temperature due to the abnormal electrical discharge and a droplet-like splashing generated from the target material adheres to the substrate.

Therefore, crystalline structure of a Cu target for sputtering has been studied so as to solve the above problem. For example, Japanese Patent Laid-Open No. 11-158614 (JP-A 11-158614) discloses an example of conventional Cu target materials, in which an average crystal grain size is suppressed to be 80 μm or less by means of a recrystallization process, so that orientation of sputtering particles is aligned and generation of coarse clusters is reduced.

As another example of the conventional Cu target materials, Japanese Patent Laid-Open No. 2002-129313 (JP-A 2002-129313) discloses a high purity Cu sputtering target, in which purity is 5N (99.999%) and an average crystal grain size is greater than 250 μm and 5000 μm or less, by which generation of particles can be suppressed.

On the other hand, as an example of conventional sputtering methods, there is a Cu-self ion sputtering method (more concretely, a method of carrying out sputtering by Cu ions in a target material atom itself without using a process gas of Ar or the like). Japanese Patent Laid-Open No. 2001-342560 (JP-A 2001-342560) discloses a high purity Cu sputtering target material to which this self ion sputtering method is applied, in which at least one of Ag and Au is doped to high purity Cu such that a total content falls within a range of 0.005 ppm to 500 ppm, in order to continue self-maintenance discharge by Cu ion for a long time.

In addition, as a still another example of the conventional sputtering materials, Japanese Patent Laid-Open No. 2004-193553 (JP-A 2004-193553) discloses a Cu alloy sputtering target material for forming a semiconductor device wiring seed layer. This conventional Cu alloy sputtering target material comprises a Cu alloy containing Ag of 0.05% by mass to 2% by mass (500 ppm to 20000 ppm) and one kind or two or more kinds of elements selected from a group consisted of V, Nb and Ta of 0.03% by mass to 0.3% by mass (300 ppm to 3000 ppm) in total.

According to JP-A 2004-193553, when a thin film as a seed layer is formed by sputtering on a TaN layer as a barrier layer in a Si-based semiconductor of an LSI (Large Scale Integration) by using the conventional Cu alloy sputtering target material described therein, aggregation by heat is decreased and generation of void in the thin film is suppressed.

### SUMMARY OF THE INVENTION

In the conventional Cu target material for sputtering disclosed by JP-A 11-158614, the abnormal electrical discharge is suppressed by setting the average crystal grain size to be a fine crystal grain size i.e. 80 μm or less. However, since the crystal grain should be miniaturized by raising a degree of work of cold rolling, a ratio of (220) plane to a total of crystal planes increases and a sputtering rate (film formation rate) decreases. Therefore, it is difficult to improve a tact time of manufacturing.

In the conventional high purity Cu sputtering target material disclosed by JP-A 2002-129313, since the coarse crystal grain size of greater than 250 μm and 5000 μm or less is used, the degree of the surface irregularity of the erosion part is increased easily. Therefore, the occurrence of the abnormal electrical discharge is frequent, and the generation of the particles increases.

Although the conventional wiring film formation techniques disclosed by JP-A 11-158614 and JP-A 2002-129313 may describe the crystal grain size of the Cu target material, these conventional wiring film formation techniques do not propose any means for realizing both of suppression of the abnormal electrical discharge due to sputtering and the high speed film formation.

On the other hand, an object of the high purity Cu sputtering target using the self ion sputtering method disclosed by JP-A 2001-342560 is to improve persistence of the self-discharge by Cu ion. An object of the conventional Cu alloy sputtering target disclosed by JP-A 2004-193553 is to improve void resistance of the semiconductor device wiring seed layer. Although the conventional thin film formation techniques disclosed by JP-A 2001-342560 and JP-A 2004-193553 describe the crystal grain size of the Cu target material, these conventional thin film formation techniques do not propose any means for realizing both of suppression of the abnormal electrical discharge due to sputtering and the high speed film formation.

Accordingly, an object of the present invention is to solve the aforementioned conventional problem, more concretely, to provide a sputtering target material by which high speed film formation is realized while suppressing an abnormal electrical discharge due to sputtering in wiring film formation by sputtering method.

In order to solve the above problem, Inventors of the present invention studied in various approaches that convexo-concaves (surface irregularity) occur due to a difference in sputtering rate (rate of scraping a surface by sputtering) depending on a crystal plane orientation of each crystal of a target material surface in the sputtering process and that a crystal grain size influences greatly on the degree of the surface irregularity as well as a relationship thereof with a working condition. As a result, the Inventors found following phenomena (1) to (4) and achieved the present invention.

(1) The sputtering rate is increased in accordance with increase in area of (111) plane and decrease in area of (220) plane with respect to a target surface (sputtering surface).

(2) Roughness of the surface irregularity of the erosion part is increased in accordance with increase in crystal grain size. On the contrary, the roughness of the surface irregularity of the erosion part is decreased and the surface is smoothened in accordance with decrease in the crystal grain size.

(3) The fine crystal grain size can be provided by adjusting the degree of work of the cold rolling to be around 40% to 70% in the manufacturing process of the target material.

(4) However, when the degree of work of the cold rolling is increased as described in (3) so as to provide the fine crystal grain size, the (111) plane orientation decreases and the (220) plane orientation increases, so that the sputtering rate decreases.

According to a feature of the invention, a sputtering target material comprises:

an oxygen free copper with a purity of 99.99% or more doped with Ag of 200 to 2000 ppm.

In the sputtering target material, an average grain size of a crystal structure is preferably 30 to 100 μm.

A ratio (220)/(111) which is a ratio of an orientation ratio of (220) plane to an orientation ratio of (111) plane calculated based on a peak intensity measurement of an X-ray diffraction at a sputtering surface is preferably 6 or less and a standard deviation indicating a dispersion in the ratio (220)/(111) is preferably 10 or less.

The sputtering target material may be manufactured by casting and rolling.

The ratio (220)/(111) is preferably greater than 1.0.

The ratio (220)/(111) is more preferably 4.5 to 5.8.

A heat treatment may be carried out on the sputtering target material after the rolling.

The heat treatment is preferably carried out at a temperature of 300 to 400° C.

The rolling may comprise a cold rolling and a degree of work of the cold rolling is 40% to 70%.

The degree of work of the cold rolling is preferably about 50%.

### ADVANTAGES OF THE INVENTION

According to the present invention, it is possible to improve the manufacturing yield by suppressing the abnormal electrical discharge and to realize the high speed film formation by increasing the sputtering rate in the wiring film formation by the sputtering method.

### BRIEF DESCRIPTION OF THE DRAWINGS

A preferred embodiment according to the present invention will be explained in conjunction with appended drawings, wherein:

FIG. 1A to 1C are graphs showing X-ray diffraction patterns of target material surfaces, wherein FIG. 1A shows an example of X-ray diffraction pattern of a target material surface in Example 1 of the present invention, FIG. 1B shows X-ray diffraction pattern of a target material surface in comparative example 1, and FIG. 1C shows X-ray diffraction pattern of a target material surface in comparative example 2.

### DETAILED DESCRIPTION OF THE PREFERRED EMBODIMENT

Next, a preferred embodiment according to the present invention will be explained below in more detailed in conjunction with appended drawings.

(Composition of a Target Material)

A sputtering target material in this preferred embodiment comprises a copper alloy containing Ag (silver) with a balance of Cu (copper) and inevitable impurities as a basic composition component. It is not necessary to contain other elements than Cu and Ag. As Cu for this copper alloy, it is preferable to use an oxygen free copper (OFC) of 4N (99.99%) or more. On the other hand, Ag is used for controlling a crystalline structure of the copper alloy. It is preferable to add Ag in a very small amount such that a resistivity of a formed film is substantially equal to a resistivity of the oxygen free copper. Further, it is preferable that an adding amount of Ag falls within a range of 0.02% to 0.2% by mass (200 ppm to 2000 ppm).

(Manufacturing of the Target Material)

This sputtering target material may be used for forming a wiring film or an electrode film on a TFT array substrate of a liquid crystal panel, for example. However, the present invention is not limited thereto.

Further, the sputtering target material may be manufactured in general through following steps, namely, casting→hot rolling→cold rolling→heat treatment→finish rolling.

In this preferred embodiment, the cold rolling is carried out for miniaturizing the crystal grain size in the manufacturing process of the sputtering target material. It is preferable to adjust the degree of work of this cold rolling to be within a range of 40% to 70%, for example. The reason for limiting the degree of work is that the average crystal grain size of the crystalline structure falls within a range of 30 μm or more and 100 μm or less (i.e. 30 μm to 100 μm), so that roughness (Ra) of the erosion part is suppressed to be about 3.0. The surface roughness of the erosion part is reduced by increasing the degree of work of the cold rolling, so that a smooth surface can be provided and the abnormal electrical discharge can be suppressed.

On the other hand, the heat treatment is carried out for recrystallizing a rolled texture. A recrystallized particle size is increased in accordance with increase in a heat treatment temperature. As to heat treatment temperature, it is preferable to carry out the heat treatment at a temperature of e.g. 300° C. to 400° C. When the heat treatment is carried out at a temperature greater than 400° C., the crystal grain size is increased. When the heat treatment is carried out at a temperature lower than 300° C., the recrystallization cannot be provided.

(Crystalline Structure of the Target Material)

In this preferred embodiment, a main feature of the sputtering target material is a configuration in which the crystal grain size of particles is homogenized by determining a content of Ag with respect to a content of Cu without containing other elements than Cu and Ag. According to this structure, it is possible to realize both of the suppression of the abnormal electrical discharge due to sputtering and the high speed film formation in the wiring film formation by sputtering method.

When the degree of work of the cold rolling is raised to miniaturize the crystal grain size for suppressing the abnormal electrical discharge, the orientation structure normally presents a specific crystal plane orientation which may decrease the sputtering rate. However, if Ag, which is a main component of the target material in this preferred embodiment, is doped to Cu within a range of 0.02% to 0.2% by mass (200 ppm to 2000 ppm), it will be possible to effectively suppress the decrease in the (111) plane orientation and the increase in the (220) plane orientation, which may decrease the sputtering rate, even though the degree of work of the cold rolling is elevated. Therefore, it is possible to effectively control the crystalline structure.

In other words, it is possible to provide an original crystal plane orientation structure in which the number of the (111) planes is large and the number of the (220) planes is smaller than the conventional art, by adding Ag within a range of 0.02% to 0.2% by mass (200 ppm to 2000 ppm) to Cu. According to this structure, it is possible to suppress a ratio of (220)/(111), i.e. a ratio of an orientation ratio of (220) plane to an orientation ratio of (111) plane to be around 5.0. Accordingly, even if the degree of work of the cold rolling is raised, the high speed film formation can be provided. It is supposed that Ag in the crystal accelerates a change in orientation from the (220) plane to the (111) plane during the recrystallization by the heat treatment after the rolling.

Herein, the sputtering surface comprises the (111) planes, the (220) planes, and other planes. The orientation ratio of the (111) plane is a percentage of an occupied area of the (111) planes to a total area of the (111) planes, the (220) planes and other planes in the sputtering surface. Similarly, the orientation ratio of the (220) plane is a percentage of an occupied area of the (220) planes to a total area of the (111) planes, the (220) planes and other planes in the sputtering surface.

The orientation of a crystal plane of the sputtering target material can be observed by using diffraction peak intensity ratio calculated by using X-ray diffraction. In this preferred embodiment, a ratio of the orientation ratio of the (220) plane to the orientation ration of the (111) plane can be calculated as follows. Firstly, a measured value of a peak intensity of each crystal plane is divided by a relative intensity ratio (a value described on a card No. 40836 of JCPDS card), since the relative intensity ratio obtained by the X-ray diffraction varies according to a diffraction plane. Herein, the JCPDS (Joint Committee on Powder Diffraction Standards) is a standard of ICDD (International Center for Diffraction Data). The calculated value for each crystal plane is further divided by a total of the calculated values for respective crystal planes to provide an orientation ratio of each crystal plane.

As to the orientation of the crystal plane of the target surface, it is preferable that the ratio of (220)/(111), i.e. the ratio of the orientation ratio of (220) plane to the orientation ratio of (111) plane is 6 or less at the peak intensity of the X-ray diffraction, wherein the plane orientation of the target surface is measured by the X-ray diffraction method. Further, it is preferable that a standard deviation in the ratio of (220)/(111) of the crystal plane orientation is 10 or less. The standard deviation indicates a dispersion of the orientation ratio in a whole area of the target surface. According to this structure, it is possible to increase the sputtering rate (film formation rate).

### EFFECTS OF THE PREFERRED EMBODIMENT

According to the preferred embodiment of the present invention, following effects can be provided.

(1) Since the increase in the resistivity of Cu can be suppressed as long as a very small amount of Ag is added to Cu. Therefore, the low resistivity required for forming the wiring film can be provided. In the sputtering process, rapid and stable electric discharge can be carried out since the resistance of the target is substantially as low as that of pure Cu.

(2) The miniaturization of the crystal grain size can be obtained by determining the degree of work within the range of 40% to 70%. As a result, the surface roughness of the erosion part can be reduced and the smooth and flat surface can be provided. Further, it is possible to control the abnormal electrical discharge.

(3) It is possible to suppress the decrease in the (111) plane orientation and the increase in the (220) plane orientation, which may decrease the sputtering rate, by adding a small amount of Ag to Cu. As a result, it is possible to increase the sputtering rate, and reduce the manufacturing cost by increasing the film formation speed.

Although the invention has been described, the invention according to claims is not to be limited by the above-mentioned embodiments and examples. Further, please note that not all combinations of the features described in the embodiments and the examples are not necessary to solve the problem of the invention.

### Examples

Next, the embodiment of the present invention will be explained in more detail by using Examples and comparative examples. In addition, these Examples are typical examples of the target material in the preferred embodiment, and the present invention is not limited to the Examples and the comparative examples.

Samples of five kinds of target material in Examples 1 to 3 and comparative examples 1 and 2 were manufactured under conditions as described below, and the properties of the samples were compared with each other. TABLE 1 shows measurement result of composition, degree of work of cold rolling, average crystal grain size, (220)/(111) orientation ratio, roughness of an erosion part, film formation rate and film resistivity of the samples of the target material in Examples 1 to 3 and comparative examples 1 and 2.

### Example 1

### Manufacturing of the Target Material

Firstly, a copper alloy comprising oxygen free copper with a purity of 99.99% (4N) comprising Ag and a balance of Cu and inevitable impurities was melt and cast for manufacturing a sample of a target material in Example 1. Then, hot rolling and cold rolling were carried out on the cast copper material. Thereafter, heat treatment was carried out on the rolled copper material. Finally, finish rolling was carried out on the heat-treated copper material to have a final configuration. As a result, the target material based on the oxygen free copper of 4N to which 200 ppm of Ag (with a width of 150 mm, a thickness of 20 mm and a length of 2 m) was manufactured.

The degree of work of the cold rolling was set to be around 50%, and the heat treatment was carried out at a temperature within a range of 300° C. to 400° C. The target material of the oxygen free copper of 4N obtained by the above process was cut to provide a sample of a target material for a sputtering experimental device (Hereinafter, referred to as “OFC target material”). The OFC target material was provided with a diameter of 100 mm and a thickness of 5 mm.

### Example 2

A sample in Example 2 was prepared from an OFC target material manufactured by similar manufacturing method under similar conditions to those in Example 1 except that 500 ppm of Ag was doped.

### Example 3

A sample in Example 3 was prepared from an OFC target material manufactured by similar manufacturing method under similar conditions to those in Example 1 except that 2000 ppm of Ag was doped.

### Comparative Example 1

A sample in comparative example 1 was prepared from an OFC target material manufactured by similar manufacturing method under similar conditions to those in Example 1 except that no Ag was doped. The degree of work of the cold rolling was raised to around 50%, and the heat treatment was carried out at a temperature within a range of 300° C. to 400° C.

### Comparative Example 2

A sample in comparative example 2 was prepared from an OFC target material manufactured by similar manufacturing method under similar conditions to those in Example 1 except that no Ag was doped. The degree of work of the cold rolling was suppressed to around 20%, and the heat treatment was carried out at a temperature within a range of 300° C. to 400° C.

(Measurement of an Orientation Degree of a Crystal Plane)

Measurement of an orientation degree of a crystal plane in the OFC target materials in Examples 1 to 3 and comparative examples 1 and 2 were carried out by using an X-ray diffractometer (fabricated by Rigaku Corporation). The X-ray diffraction intensity for each sample was measured in an arbitrary range by X-ray diffraction method (28 method).

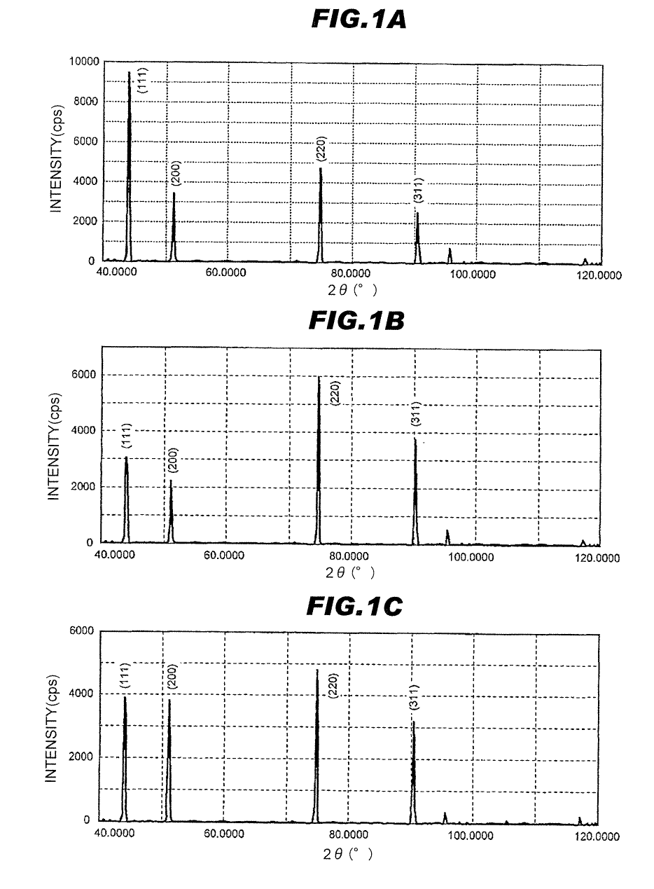

FIG. 1A shows a result of X-ray diffraction measurement of a surface (sputtering surface) of the OFC target material in Example 1, FIG. 1B a result of X-ray diffraction measurement of a surface (sputtering surface) of the OFC target material in the comparative example 1, and FIG. 1C a result of X-ray diffraction measurement of a surface (sputtering surface) of the OFC target material in the comparative example 2. In FIGS. 1A to 1C, a vertical axis indicates X-ray intensity (count per second: cps) and a horizontal axis indicates a diffraction angle of 2θ (°).

A surface (sputtering surface) of samples of five kinds of the OFC target material in Examples 1 to 3 and the comparative examples 1 and 2 were polished, and the X-ray diffraction for each sample was measured. Based on the measurement result, the orientation ratio of (220)/(111) was calculated by the method as described above. At this time, since a dispersion in the ratio of the X-ray diffraction peak intensity of a bulk-type OFC target material surface is greater than that of a powder-type sample, the X-ray diffraction peak intensity was measured at a plurality of surface points to calculate a mean value of the orientation ratio of (220)/(111).

(Analysis of the Crystalline Structure)

As clearly understood from FIG. 1A and TABLE 1, the average crystal grain size was miniaturized to be 30 μm in the OFC target material containing Ag in Example 1. The orientation ratio of (220)/(111) was 4.5 (i.e. equal to or less than 6), and the (220) plane orientation was little. Similarly to Example 1, the average crystal grain size and the orientation ratio of (220)/(111) orientation ratio in the OFC target materials containing Ag in Examples 2 and 3 satisfied target ranges.

On the other hand, as clearly understood from FIG. 1B and TABLE 1, the average crystal grain size was miniaturized to be 30 μm in the OFC target material containing no Ag in the comparative example 1, by increasing the degree of work of the cold rolling. However, the orientation ratio of (220)/(111) was 13.3 and the (220) plane orientation was much. Therefore, in the OFC target material in the comparative example 1, the orientation ratio of (220)/(111) was out of the target range.

Further, as clearly understood from FIG. 1C and TABLE 1, the orientation ratio of (220)/(111) in each of the OFC target materials containing no Ag in the comparative example 2 was equal to or less than 6 and the (220) plane orientation was little, similarly to those in Examples 1 to 3. However, the average crystal grain size was increased to be 100 μm, so that the average crystal grain size was out of the target range.

(Roughness Measurement of an Erosion Part)

By using a sputtering equipment for experiment (SH-350 fabricated by ULVAC, Inc.), roughness (Ra) of an erosion part formed by sputtering for a long time was evaluated. Sputtering conditions were as follows. Process gas was Ar, a pressure in sputtering was 0.5 Pa, and discharge power was 2 kW. Sputtering was carried out for 80 minutes by DC sputtering with the use of direct current power supply. The measurement of roughness was carried out by using a contact type roughness measuring apparatus (SURFCOM 1800D/DH fabricated by Tokyo Seimitsu Co., Ltd.). An arithmetic average roughness (Ra) of the erosion part was measured under a condition that a measurement length is 1.25 mm.

(Roughness Analysis of the Erosion Part)

As clearly understood from TABLE 1, the roughness of the erosion part of each of the OFC target materials in Examples 1 to 3 was 3.4 μm or 3.5 μm, since the average crystal grain size was small, i.e. 30 μm. Namely, the surface of the erosion part was smooth. Therefore, these OFC target materials satisfied a target range.

As clearly understood from TABLE 1, the roughness of the erosion part of each of the OFC target materials in the comparative example 1 was 3.6 μm, since the average crystal grain size was small, i.e. 30 μm. Namely, the surface of the erosion part was smooth.

As clearly understood from TABLE 1, the roughness of the erosion part of each of the OFC target materials in the comparative example 2 was 6.5 μm. Namely, the roughness of the erosion part in the comparative example 2 was significantly greater than those of the erosion parts in Examples 1 to 3 and the comparative example 1. Namely, the roughness of the erosion part in the comparative example 2 was out of the target range.

Herein, the Inventors of the present invention have already known from studies until now that the roughness of the erosion part is increased in accordance with the increase in the crystal grain size. A relationship between the roughness and the occurrence frequency of the abnormal electrical discharge is not quantitatively established, since it is also influenced by the sputtering condition and accumulated total time of sputtering. However, it is found that the abnormal electrical discharge easily occurs when the crystal grain size exceeds 100 μm, based on numerous analysis results. Therefore, a value of the average crystal grain size of the OFC target material containing no Ag in the comparative example 2 is an upper limit for suppressing the abnormal electrical discharge.

(Measurement of Film Formation Rate and Film Resistivity)

Film formation rate and film resistivity of a sputtering film with the use of the OFC target materials in Examples 1 to 3 and the comparative examples 1 and 2 were measured. Sputtering conditions were as follows. Process gas was Ar, a pressure in sputtering was 0.5 Pa, and discharge power was 2 kW. Sputtering film formation on a glass substrate was carried out for 3 minutes by DC sputtering. The film formation rate was calculated as follows. Firstly, a film thickness of the sputtering film was measured by a laser microscope (VK-8700 fabricated by KEYENCE Corporation) and the measured value of the film thickness was divided by a film formation time (3 minutes). The film resistivity was measured by Van der Pauw method.

(Analysis of the Film Formation Rate and the Film Resistivity)

As clearly understood from TABLE 1, a very small amount of Ag wad doped and the orientation ratio of (220)/(111) was 6 or less in the OFC target materials in Examples 1 to 3, so that the film formation rate was high, i.e. 103 nm/min to 107 nm/min. The film resistivity was 2.0 μΩm to 2.1 μΩcm. The film formation rate and the film resistivity of these OFC target materials satisfied the target ranges.

As clearly understood from TABLE 1, in the OFC target materials in the comparative example 1, the film resistivity was 2.0 μΩcm, similarly to that in Example 1. However, the film formation rate was 82 nm/min, which is lower than the film formation rate in Example 1 to 3 and the comparative example 2.

As clearly understood from TABLE 1, in the OFC target materials in the comparative example 2, the film resistivity was 2.0 μΩcm, similarly to that in Example 1. The film formation rate was 105 nm/min, which is higher than the film formation rate in the comparative example 1.

Accordingly, it was found as follows based on the experimental results. In the Cu sputtering target material manufactured by casting and rolling process, when the crystal grain size is miniaturized by raising the degree of work of the cold rolling so as to suppress the abnormal electrical discharge, the (111) plane orientation is decreased and the (220) plane orientation is increased at the surface of the target material. Such orientation structure decreases the film formation rate. Therefore, it is difficult to realize both of the high speed film formation and the suppression of the abnormal electrical discharge.

According to the OFC target materials in Examples 1 to 3, since a very small amount of Ag is doped, even if the degree of work of the cold rolling is raised, it is possible to suppress the decrease in the (111) plane orientation and the increase in the (220) plane orientation, so that it is possible to realize both of suppression of the abnormal electrical discharge and the high speed film formation.

For example, in the case of forming a wiring film on a TFT array substrate of a liquid crystal panel by the sputtering method by using either of the OFC target materials in Examples 1 to 3, it is possible to enhance the yield by suppressing the abnormal electrical discharge and to reduce the manufacturing cost by carrying out the high speed film formation. In addition, the film resistivity of the OFC target material doped with a very small amount of AG is substantially equal to that of pure Cu, and a film resistivity required for forming the wiring film can be provided.

The orientation ratio of (220)/(111) and the film formation rate in the OFC target material in the comparative example 1 are out of the target ranges. On the other hand, the roughness of the erosion part in the OFC target material in the comparative example 2 is very large. In the OFC target materials in the comparative examples 1 and 2, acceptable properties cannot be provided in a comprehensive manner.

TABLE 1

| | | Degree | Average | | Roughness | | |
|---|---|---|---|---|---|---|---|
| | | of Work | crystal | | (Ra) of | Film | |
| | | of Cold | grain | Orientation | erosion | formation | Film |
| | | rolling | size | ratio of | part | rate | resistivity |
| | Composition | (%) | (μm) | (220)/(111) | (μm) | (nm/min) | (μ Ω cm) |
| Example 1 | OFC of 4N | 50 | 30 | 4.5 | 3.5 | 103 | 2.0 |
| | doped with | | | | | | |
| | Ag of 200 | | | | | | |
| | ppm | | | | | | |
| Example 2 | OFC of 4N | 50 | 30 | 5.8 | 3.4 | 106 | 2.0 |
| | doped with | | | | | | |
| | Ag of 500 | | | | | | |
| | ppm | | | | | | |
| Example 3 | OFC of 4N | 50 | 30 | 5.6 | 3.4 | 107 | 2.1 |
| | doped with | | | | | | |
| | Ag of 2000 | | | | | | |
| | ppm | | | | | | |
| Comparative | OFC of 4N | 50 | 30 | 13.3 | 3.6 | 82 | 2.0 |
| example 1 | | | | | | | |
| Comparative | OFC of 4N | 20 | 100 | 5.4 | 6.5 | 105 | 2.0 |
| example 2 | | | | | | | |

What is claimed is:

1. A sputtering target material comprising:
an oxygen free copper with a purity of 99.99% or more doped with Ag of 200 to 2000 ppm.

2. The sputtering target material according to claim 1, wherein an average grain size of a crystal structure is 30 to 100 μm.

3. The sputtering target material according to claim 1, wherein a ratio (220)/(111) which is a ratio of an orientation ratio of (220) plane to an orientation ratio of (111) plane calculated based on a peak intensity measurement of an X-ray diffraction at a sputtering surface is 6 or less and a standard deviation indicating a dispersion in the ratio (220)/(111) is 10 or less.

4. The sputtering target material according to claim 2, wherein a ratio (220)/(111) which is a ratio of an orientation ratio of (220) plane to an orientation ratio of (111) plane calculated based on a peak intensity measurement of an X-ray diffraction at a sputtering surface is 6 or less and a standard deviation indicating a dispersion in the ratio (220)/(111) is 10 or less.

5. The sputtering target material according to claim 1, wherein the sputtering target material is manufactured by casting and rolling.

6. The sputtering target material according to claim 3, wherein the ratio (220)/(111) is greater than 1.0.

7. The sputtering target material according to claim 3, wherein the ratio (220)/(111) is 4.5 to 5.8.

8. The sputtering target material according to claim 5, wherein a heat treatment is carried out on the sputtering target material after the rolling.

9. The sputtering target material according to claim 8, wherein the heat treatment is carried out at a temperature of 300 to 400° C.

10. The sputtering target material according to claim 5, wherein the rolling comprises a cold rolling and a degree of work of the cold rolling is 40% to 70%.

11. The sputtering target material according to claim 10, wherein the degree of work of the cold rolling is about 50%.
